(19) United States
(12) Patent Application Publication
(10) Pub. No.: US 2010/0081279 A1
(43) Pub. Date: Apr. 1, 2010

(54) Method for Forming Through-base Wafer Vias in Fabrication of Stacked Devices

(75) Inventors: Bentley J. Palmer, Phoenix, AZ (US); Rebecca A. Sawayda, Gilbert, AZ (US)

Correspondence Address: AIR PRODUCTS AND CHEMICALS, INC.;PATENT DEPARTMENT, 7201 HAMILTON BOULEVARD, ALLENTOWN, PA, 181951501, US

(73) Assignee: DUPONT AIR PRODUCTS NANOMATERIALS LLC, Allentown, PA (US)

(21) Appl. No.: 12/242,002

(22) Filed: Sep. 30, 2008

(51) Int. Cl. H01L 21/44

(52) U.S. Cl. 438/667; 257/E21.476

(57) ABSTRACT

An effective method for forming through-base wafer vias in the fabrication of stacked devices is described. The base wafer can be a silicon wafer in which case the method relates to TSV (through-silicon via) technology. The method affords high removal rates of both silicon and metal (e.g., copper) under appropriate conditions and is tuneable with respect to base wafer material to metal selectivity.

### FIELD OF THE INVENTION

This invention is in the field of through-base wafer technology for thinning the backsides of work base wafers prior to their assembly into stacked devices. A specific example of through-base wafer technology is where the base wafer(s) is a silicon wafer in which case this technology is termed through-silicon via (TSV) technology.

The invention relates to improved methods for effecting through-base wafer technology that utilizes chemical mechanical planarization (CMP) with high removal rates for removal of both base wafer material (e.g., silicon) and metal.

### BACKGROUND OF THE INVENTION

3D integration promises to reduce system form factor through direct stacking and interconnection of chips, made using different technologies, into a single system. These interconnects consist of small and deep through wafer vias in the form of metal (e.g., copper) nails. One of the enabling technologies to achieve 3D stacks, is thinning of the base wafer on which the semiconductor circuits (integrated circuits) are disposed. Semiconductor wafer manufacturing typically involves hundreds of discrete operations on the surface of a silicon wafer, which are performed over a number of weeks. In order to minimize wafer breakage and damage, which can easily occur during this lengthy manufacturing process, the base wafers are typically 300- to 800-microns thick. The base wafer is thinned by removing base wafer material (e.g., silicon in case of silicon wafer processing) from the backside of the wafer. This can involve gluing the front side of a wafer comprising an integrated circuit thereon to a carrier wafer, and then grinding and then CMP of backside of the wafer to achieve a thickness of about 10 to 50 microns while the wafer is temporarily glued to a carrier. This thinning exposes conductive vias extending at least partially through (e.g., completely through) the base wafer.

The grinding step has been considered necessary because CMP processes, especially for silicon, have historically been very limited in rate. However, wafer delamination and destruction, as well as destruction of the grinding wheels, has been an unfortunate but not uncommon problem with grinding of the backside of a silicon wafer. This is particularly problematic because the wafer represents the end-product of a number of elaborate fabrication and quality control steps, and failures of these wafers therefore represent significant economic loss. Further, destruction of grinding wheels results in considerable line down time as well as resulting in additional economic loss.

What is needed is a CMP process capable of polishing base wafer material (e.g., silicon in case of a silicon wafer) at a sufficiently high rate so that the grinding step can be eliminated. Even in processes where back-side material is ground in a grinding step, the use of high removal rate CMP can allow manufacturers to specify less material that needs to be ground from the backside of wafers.

Chemical mechanical planarization (chemical mechanical polishing, CMP) for planarization of semiconductor substrates is now widely known to those skilled in the art and has been described in numerous patents and open literature publications. Some introductory references on CMP are as follows: “Polishing Surfaces for Integrated Circuits”, by B. L. Mueller and J. S. Steckenrider, Chemtech, February, 1998, pages 38-46; H. Landis et al., Thin Solids Films, 220 (1992), page 1; and “Chemical-Mechanical Polish” by G. B. Shinn et al., Chapter 15, pages 415-460, in Handbook of Semiconductor Manufacturing Technology, editors: Y. Nishi and R. Doering, Marcel Dekker, New York City (2000).

In a typical CMP process, a substrate (e.g., a wafer) is placed in contact with a rotating polishing pad attached to a platen. A CMP slurry, typically an abrasive and chemically reactive mixture, is supplied to the pad during CMP processing of the substrate. During the CMP process, the pad (fixed to the platen) and substrate are rotated while a wafer carrier system or polishing head applies pressure (downward force) against the substrate. The slurry accomplishes the planarization (polishing) process by chemically and mechanically interacting with the substrate film being planarized due to the effect of the downward force and the rotational movement of the pad relative to the substrate. Polishing is continued in this manner until the desired film on the substrate is removed with the usual objective being to effectively planarize the substrate. Typically metal CMP slurries contain an abrasive material, such as silica or alumina, suspended in an oxidizing, aqueous medium.

Silicon based semiconductor devices, such as integrated circuits (ICs), typically include a dielectric layer. Multilevel circuit traces, typically formed from aluminum or an aluminum alloy or copper, are patterned onto the dielectric layer substrate. These are numerous types of layers that can be polished by CMP, for example, silicon nitride, interlayer dielectrics (ILD) such as silicon oxide and low-k films including carbon-doped oxides; metal layers such as tungsten, copper, aluminum, etc., which are used to connect the active devices; barrier layer materials such as titanium, titanium nitride, tantalum, tantalum nitride, noble metals, etc.

CMP processing is often employed to remove and planarize excess metal at different stages of semiconductor manufacturing. Various metals and metal alloys have been used at different stages of semiconductor manufacturing, including tungsten, aluminum, copper, tantalum, tantalum nitride, titanium, titanium nitride, ruthenium, platinum, iridium, gold, and combinations thereof. For example, one way to fabricate a multilevel copper interconnect or planar copper circuit traces on a dielectric substrate is referred to as the damascene process. In a semiconductor manufacturing process typically used to form a multilevel copper interconnect, metallized copper lines or copper vias are formed by electrochemical metal deposition followed by copper CMP processing. In a typical process, the interlevel dielectric (ILD) surface is patterned by a conventional dry etch process to form vias and trenches for vertical and horizontal interconnects and make connection to the sublayer interconnect structures. The patterned ILD surface typically is coated with an adhesion-promoting layer such as titanium or tantalum and/or a diffusion barrier layer such as titanium nitride or tantalum nitride over the ILD surface and into the etched trenches and vias. The adhesion-promoting layer and/or the diffusion barrier layer is then overcoated with copper, for example, by a seed copper layer and followed by an electrochemically deposited copper layer. Electro-deposition is continued until the structures are filled with the deposited metal. Finally, CMP processing is used to remove the copper overlayer, adhesion-promoting layer, and/or diffusion barrier layer, until a planarized surface with exposed elevated portions of the dielectric (silicon dioxide and/or low-k) surface is obtained. The vias and trenches remain filled with electrically conductive copper forming the circuit interconnects. The adhesion-promoting layer plus diffusion barrier layer is typically collectively referred to as the “barrier layer.”

A multi-step copper CMP process may be employed to achieve local and global planarization in the production of IC chips, referred to as a step 1 copper CMP process, followed by a barrier layer CMP process. In relation to copper CMP, the current state of this technology involves use of a two-step process. During step 1 of a copper CMP process, the overburden copper is removed and planarized. Then step 2 of the copper CMP process follows to remove the barrier layer materials and achieve both local and global planarization. The barrier layer CMP process is frequently referred to as a barrier or step 2 copper CMP process. The ratio of the removal rate of copper to the removal rate of dielectric material is called the “selectivity” for removal of copper in relation to dielectric material during CMP processing of substrates comprised of copper, barrier layer materials, and dielectric material. The ratio of the removal rate of barrier layer materials to the removal rate of copper is called the “selectivity” for removal of barrier layer materials in relation to copper during CMP processing of substrates comprised of copper, barrier layer materials, and dielectric materials. Barrier layer materials include tantalum, tantalum nitride, tungsten, noble metals such as ruthenium and ruthenium oxide, and combinations thereof.

When CMP slurries over-polish copper layers they may create a depression or “dishing” effect in the copper vias and trenches. This problem is made worse with through-silicon-vias as the vias often have a large diameter, e.g., 100 μm diameter. This feature distortion is unacceptable due to lithographic and other constraints in semiconductor manufacturing. Another feature distortion that is unsuitable for semiconductor manufacturing is called “erosion.” Erosion is the topography difference between a field of dielectric and a dense array of copper vias or trenches. In CMP, the materials in the dense array may be removed or eroded at a faster rate than the surrounding field of dielectric. This causes a topography difference between the field of dielectric and the dense copper array.

A number of systems for CMP of copper have been disclosed. A few illustrative examples are listed next. Kumar et al. in an article entitled “Chemical-Mechanical Polishing of Copper in Glycerol Based Slurries” (Materials Research Society Symposium Proceedings, 1996) disclose a slurry that contains glycerol and abrasive alumina particles. An article by Gutmann et al. entitled “Chemical-Mechanical Polishing of Copper with Oxide and Polymer Interlevel Dielectrics” (Thin Solid Films, 1995) discloses slurries based on either ammonium hydroxide or nitric acid that may contain benzotriazole (BTA) as an inhibitor of copper dissolution. Luo et al. in an article entitled “Stabilization of Alumina Slurry for Chemical-Mechanical Polishing of Copper” (Langmuir, 1996) discloses alumina-ferric nitrate slurries that contain polymeric surfactants and BTA. Carpio et al. in an article entitled “Initial Study on Copper CMP Slurry Chemistries” (Thin Solid Films, 1995) disclose slurries that contain either alumina or silicon particles, nitric acid or ammonium hydroxide, with hydrogen peroxide or potassium permanganate as an oxidizer.

Typically, step 1 copper CMP slurries can remove copper at rates of 4000 angstroms per minute, often as high as 10,000 angstroms per minute, with less than 7 psi downforce. Such step 2 copper CMP slurries typically have a Cu to dielectric selectivity (or Cu to barrier layer selectivity) between 10 and 100. Generally, after removal of overburden copper in step 1, polished wafer surfaces have non-uniform local and global planarity due to differences in the step heights at various locations of the wafer surfaces. Low density features tend to have higher copper step heights whereas high density features tend to have low step heights. Due to differences in the step heights after step 1, selective slurries are highly desirable for step 2 copper CMP for the selective removal of barrier layer materials in relation to copper and for the selective removal of dielectric materials in relation to copper. Typically, step 2 copper CMP slurries can remove copper at rates of 2500 angstroms per minute or less with 3 psi downforce. Such step 2 copper CMP slurries typically have a Cu to dielectric selectivity between 0.1 and 1.5, and a Cu to barrier layer selectivity between 0.1 and 1.5.

A typically used CMP slurry has two actions, a chemical component and a mechanical component. There are a number of theories as to the mechanism for chemical mechanical polishing of copper. An article by Zeidler et al. (Microelectronic Engineering, 1997) proposes that the chemical component forms a passivation layer on the copper changing the copper to a copper oxide. The copper oxide has different mechanical properties, such as density and hardness, than metallic copper and passivation changes the polishing rate of the abrasive portion. The above article by Gutmann et al. discloses that the mechanical component abrades elevated portions of copper and the chemical component then dissolves the abraded material. The chemical component also passivates recessed copper areas minimizing dissolution of those portions.

In the case of CMP of metals, the chemical action is generally considered to take one of two forms. In the first mechanism, the chemicals in the solution react with the metal layer to continuously form an oxide layer on the surface of the metal. This generally requires the addition of an oxidizer to the solution such as hydrogen peroxide, ferric nitrate, etc. Then the mechanical abrasive action of the particles continuously and simultaneously removes this oxide layer. A judicious balance of these two processes obtains optimum results in terms of removal rate and polished surface quality.

In the second mechanism, no protective oxide layer is formed. Instead, the constituents in the solution chemically attack and dissolve the metal, while the mechanical action is largely one of mechanically enhancing the dissolution rate by such processes as continuously exposing more surface area to chemical attack, raising the local temperature (which increases the dissolution rate) by the friction between the particles and the metal, and enhancing the diffusion of reactants and products to and away from the surface by mixing and by reducing the thickness of the boundary layer.

### BRIEF SUMMARY OF THE INVENTION

In one embodiment, the invention is a method for constructing an assembly comprising at least two base wafers, said method comprising:

a) providing a first base wafer having front and back sides, wherein the front side comprises integrated circuits disposed thereon and wherein the base wafer comprises at least one conductive via comprising conductive metal and extending from the front of the base wafer at least partially through the base wafer;

b) affixing the front side of the base wafer having integrated circuits thereon to a carrier;

c) contacting the back side of the base wafer with a polishing pad and a first CMP slurry, said first CMP slurry comprising:
1) a liquid carrier;
2) between 0.1% and 20% by weight of an oxidizer selected from the group consisting of periodic acid or salt thereof, perchloric acid or salt thereof, a persulfate salt or acid thereof, a permanganate salt or acid thereof, ozone, silver oxide, and elemental fluorine;
3) an abrasive; and
4) at least one metal chelating agent, and
d) polishing the backside of the base wafer until at least one conductive via is exposed, wherein the first base wafer is polished using the first CMP slurry at a rate of at least 5,000 angstroms per minute at 7 psi or less of down-force.

In another embodiment, the invention is a method for constructing an assembly comprising at least two base wafers, said method comprising:

a) providing a first base wafer having front and back sides, wherein the front side comprises integrated circuits disposed thereon and wherein the base wafer comprises at least one conductive via comprising conductive metal and extending from the front of the base wafer at least partially through the base wafer;

b) contacting the back side of the base wafer with a polishing pad and a first CMP slurry, said first CMP slurry comprising:
1) a liquid carrier;
2) between 0.1% and 20% by weight of an oxidizer selected from the group consisting of periodic acid or salt thereof, perchloric acid or salt thereof, a persulfate salt or acid thereof, a permanganate salt or acid thereof, ozone, silver oxide, and elemental fluorine;
3) an abrasive which may be suspended in the slurry, which may be affixed to a polishing pad, or both; and
4) at least one metal chelating agent, and

c) polishing the backside of the base wafer until at least one conductive via is exposed, wherein the first base wafer is polished using the first CMP slurry at a rate of at least 5,000 angstroms per minute at 7 psi or less of down-force.

In another embodiment, the invention is a method for constructing an assembly comprising at least two base wafers, said method comprising:

a) providing a first base wafer having front and back sides and a thickness between 100 and about 800 microns, wherein the front side comprises integrated circuits disposed thereon;

b) affixing the front side of the base wafer having integrated circuits thereon to a carrier;

c) contacting the back side of the base wafer with a polishing pad and a first CMP slurry, said first CMP slurry comprising:
1) a liquid carrier;
2) between 0.1% and 20% by weight of an oxidizer selected from the group consisting of periodic acid or salt thereof, perchloric acid or salt thereof, a persulfate salt or acid thereof, a permanganate salt or acid thereof, ozone, silver oxide, and elemental fluorine;
3) an abrasive which may be suspended in the slurry, which may be affixed to a polishing pad, or both; and
4) at least one metal chelating agent selected from an organic acid or an amino-carboxylic acid, and

d) polishing the backside of the base wafer until the base wafer thickness is reduced to between 30 and 80 microns, wherein the first base wafer is polished using the first CMP slurry at a rate of at least 5,000 angstroms per minute at 7 psi or less of down-force.

In an embodiment, the invention is a method for constructing an assembly comprising two wafers, said method comprising:

a) providing a silicon base wafer having front and back sides, wherein the front side comprises integrated circuits disposed thereon and wherein the base wafer comprises at least one conductive via comprising conductive metal and extending from the front of the base wafer at least partially through the base wafer;

b) affixing the front side of the silicon base wafer having integrated circuits thereon to a carrier;

c) contacting the back side of the silicon base wafer with a polishing pad and a first CMP slurry, said first CMP slurry comprising:
1) water;
2) between 0.05% and 10% by weight of periodic acid;
3) an abrasive; and
4) at least one organic acid or an amino-carboxylic acid, and

d) polishing the backside of the silicon base wafer until at least one conductive via is exposed, wherein the first base wafer is polished using the first CMP slurry at a rate of at least 10,000 angstroms per minute at 7 psi or less of down-force.

### DETAILED DESCRIPTION OF THE INVENTION

As explained supra, this invention is a method for constructing an assembly containing two or more base wafers that, when assembled, is a stacked device. A key aspect of this method entails use of chemical mechanical planarization (CMP) to effect planarization of the backsides of base wafer(s) with high removal rates of both base wafer material (e.g., silicon) and conductive metal (e.g., copper). Furthermore, another key aspect of this method is that it affords base wafer: conductive metal selectivity values ranging from about 0.5 to about 2.0 that are tuneable within this range such that highly planarized backside surfaces of post-CMP base wafers having exposed conductive metal nails are realized

The compositions employed for CMP processing in the method of this invention are key to realizing simultaneously the above-described desirable properties relating to high removal rates and relatively low selectivities (0.5-2.0). In view of this consideration, the properties of the components in the CMP slurry compositions utilized in the method of this invention will be described in detail first.

The liquid carrier present in the compositions that are utilized in the methods of this invention can be any liquid at ambient conditions that has suitable properties for use in a CMP slurry. Suitable liquid carriers are those that solubilize most or all of the components apart from the abrasive(s) and which afford relatively stable dispersions of the abrasive(s). Suitable liquid carriers include, but are not limited to, water and mixtures of water and organic compound(s) that are either soluble or dispersible in water. As explained infra, various organic solvents can be employed alone or with water as liquid carrier.

In an embodiment, the oxidizing agent is selected from the group consisting of periodic acid, perchloric acid, a persulfate salt or acid thereof, a permanganate salt or acid thereof, ozone, silver oxide, and elemental fluorine. The persulfate salt can either be a monopersulfate or a dipersulfate (i.e., salts of monopersulfuric acid or dipersulfuric acid. Mixtures of these oxidizing agents can be used.

In an embodiment, the oxidizing agent is selected from the group consisting of periodic acid, perchloric acid, monopersulfuric acid, dipersulfuric acid, and salts thereof, and mixtures thereof. In another embodiment, the oxidizing agent is selected from the group consisting of periodic acid and perchloric acid. In another embodiment, the oxidizing agent comprises, consists essentially of, or consists of periodic acid.

The oxidizing agent in the compositions of this invention is present in the slurry in a concentration of about 0.01 weight % to about 20 weight %. In an embodiment, the oxidizing agent is present in a concentration of about 0.02 weight % to about 10 weight % of the total weight of the slurry. In another embodiment, the oxidizing agent is present in a concentration of about 0.1% weight % to about 5 weight % of the total weight of the slurry. In an embodiment, the oxidizing agent is present in a concentration between 0.5 weight % and 2 weight % and, in yet another embodiment, the oxidizing agent is present at a concentration between 0.75 weight % and 1.5 weight %. When the oxidizing agent is periodic acid, a preferred PIA concentration is between 0.5 weight % and 2 weight %, more preferably between 0.75 weight % and 1.5 weight percent, for example, between 1 weight % and 1.25 weight %.

At least one metal chelating agent is present in the CMP slurry compositions utilized during CMP processing according to the method of this invention. Suitable chelating agents that may be added to the slurry composition include, but are not limited to, ethylenediaminetetracetic acid, N-hydroxyethylethylenediaminetriacetic acid, nitrilotriacetic acid, diethylenetriaminepentacetic acid, ethanoldiglycinate, glycine, tricine, citric acid, 2,3-butanedione dioxime (dimethylglyoxime), guanindine carbonate, and mixtures thereof.

In an embodiment, the chelating agent is an aminocarboxylic acid having the structure H₂N—R—COOH, where R is a straight or branched alkyl group having between 1 and 6 carbon atoms. In an embodiment, the chelating agent is an aminocarboxylic acid having the structure H₂N—R—COOH, where R is a straight or branched alkyl group having between 1 and 6 carbon atoms, and further comprises hydroxyl-carboxylic acid. In an embodiment, the chelating agent is NH₂—CH₂—COOH (glycine). In an embodiment, the chelating agent is selected from the group consisting of glycine and aminosulfuric acid. In another embodiment, the chelating agent is glycine or citric acid or mixtures thereof. In an embodiment, the chelating agent is glycine in combination with citric acid. In an embodiment, the chelating agent is selected from the group consisting of glycine, tricine, citric acid, 2,3-butanedione dioxime and ethylenediaminetetracetic acid, for example in an amount between about 0.01% by weight to about 0.15% by weight. In an embodiment, the chelating agent is a citrate salt between 0.01% by weight and 5% by weight in the slurry. In an embodiment, the chelating agent is ammonium oxalate monohydrate between about 0.01% by weight to about 0.15% by weight.

The chelating agent may be present in the slurry composition in a concentration of about 0.03 weight % to about 10 weight % based on the total weight of the slurry. In an embodiment, the chelating agent is present in a concentration of about 0.1 weight % to about 5 weight % based on the total weight of the slurry. In another embodiment, the chelating agent is present in a concentration of about 0.5 weight % to about 4 weight % of the total weight of the slurry. In another embodiment, the chelating agent is present in a concentration of about 0.04 weight % to about 0.1 weight %.

Both standard (unmodified) abrasives and surface-modified abrasives can be employed in this invention when applicable. Suitable unmodified abrasives include, but are not limited to, silica, alumina, titania, zirconia, germania, ceria, and co-formed products thereof, and mixtures thereof. A surface-modified abrasive obtained by treatment of an unmodified abrasive (e.g., silica) with an inorganic or organometallic compound can also be employed in this invention. Suitable inorganic compounds for modification include boric acid, sodium aluminate, and potassium aluminate. Suitable organometallic compounds for modification include aluminum acetate, aluminum formate, and aluminum propionate. Suitable abrasives include, but are not limited to, colloidal products, fumed products, and mixtures thereof. Some specific examples of surface-modified abrasives are modification of silica with boric acid to give boron surface-modified silica and modification of silica with sodium aluminate or potassium aluminate to give aluminate surface-modified silica.

Silica and surface-modified silica are preferred abrasive materials used in the present invention. The silica may be, for example, colloidal silica, fumed silica and other silica dispersions; however, the preferred silica is colloidal silica or surface-modified colloidal silica.

In most embodiments, the abrasive is present in the slurry in a concentration of about 0.001 weight % to about 30 weight % of the total weight of the slurry. In one embodiment, the abrasive is present in a concentration of about 0.5 weight % to about 20 weight % of the total weight of the slurry. In another embodiment, the abrasive is present in a concentration of about 1 weight % to about 10 weight % of the total weight of the slurry, and, in yet another embodiment, the abrasive is present in a concentration of about 1 weight % to about 5 weight %.

Other chemicals that may be added to the CMP slurry composition include, for example, additional oxidizing agents, water-miscible solvents, surfactants, pH adjusting agents, acids, corrosion inhibitors, fluorine-containing compounds, chelating agents, non-polymeric nitrogen-containing compounds, and salts.

Suitable water-miscible solvents that may be added to the slurry composition include, for example, ethyl acetate, methanol, ethanol, propanol, isopropanol, butanol, glycerol, ethylene glycol, and propylene glycol, and mixtures thereof. The water-miscible solvents may be present in the slurry composition in a concentration of about 0 weight % to about 4 weight % in one embodiment, of about 0.1 weight % to about 2 weight % in another embodiment, and, in a concentration of about 0.5 weight % to about 1 weight % in yet another embodiment; each of these weight % values is based on the total weight of the slurry. The preferred types of water-miscible solvents are isopropanol, butanol, and glycerol.

Suitable surfactant compounds that may be added to the slurry composition include, for example, any of the numerous nonionic, anionic, cationic or amphoteric surfactants known to those skilled in the art. The surfactant compounds may be present in the slurry composition in a concentration of about 0 weight % to about 1 weight % in one embodiment, of about 0.0005 weight % to about 1 weight % in another embodiment, and, in a concentration of about 0.001 weight % to about 0.5 weight % in yet another embodiment; each of these weight % values is based on the total weight of the slurry. The preferred types of surfactants are nonionic, anionic, or mixtures thereof and are most preferably present in a concentration of about 10 ppm to about 1000 ppm of the total weight of the slurry. Nonionic surfactants are preferred.

The pH-adjusting agent is used to improve the stability of the polishing composition, to improve the safety in use or to meet the requirements of various regulations. As a pH-adjusting agent to be used to lower the pH of the polishing composition of the present invention, hydrochloric acid, nitric acid, sulfuric acid, chloroacetic acid, tartaric acid, succinic acid, citric acid, malic acid, malonic acid, various fatty acids, various polycarboxylic acids may be employed. On the other hand, as a pH-adjusting agent to be used for the purpose of raising the pH, potassium hydroxide, sodium hydroxide, ammonia, tetramethylammonium hydroxide, ethylenediamine, ammonium hydroxide, piperazine, polyethyleneimine, etc., may be employed. The polishing composition of the present invention is not particularly limited with respect to the pH, but it is usually adjusted to pH 5 to 12. In one embodiment, a suitable slurry pH basic, for example is from about 7 to about 11. In another embodiment, a suitable slurry pH is from about 8 to about 10. In another embodiment the pH is between 10.01 and 10.49. In an embodiment, the pH is between 10.5 and 11.5. In another embodiment, the pH is between 11.6 and 13.

Other suitable acid compounds that may be added (in place of or in addition to the pH-adjusting acids mentioned supra) to the slurry composition include, but are not limited to, formic acid, acetic acid, propanoic acid, butanoic acid, pentanoic acid, hexanoic acid, heptanoic acid, octanoic acid, nonanoic acid, lactic acid, hydrochloric acid, nitric acid, phosphoric acid, sulfuric acid, hydrofluoric acid, malic acid, tartaric acid, gluconic acid, citric acid, phthalic acid, pyrocatechoic acid, pyrogallol carboxylic acid, gallic acid, tannic acid, and mixtures thereof. These acid compounds may be present in the slurry composition in a concentration of about 0 weight % to about 5 weight % of the total weight of the slurry.

Suitable corrosion inhibitors that may be added to the slurry composition include, for example, 1,2,4-triazole, benzotriazole, 6-tolylytriazole, tolyltriazole derivatives, 1-(2,3-dicarboxypropyl)benzotriazole, and branched-alkylphenol-substituted-benzotriazole compounds. Some useful commercial corrosion inhibitors include Mafo13MOD1, Iconol TDA-9, and Iconol TDA-6 (all available from BASF Corp., Florham Park, N.J.), and Daetec MI-110 (available from Daetec L.L.C., Camarmillo, Calif.). In an embodiment, the corrosion inhibitor is a phenolic compound, and in another embodiment the phenolic compound is catechol present at a level between 0.001% by weight (10 ppm) and 5% by weight. The corrosion inhibitor may be present in the slurry in a concentration of about 0 ppm to about 4000 ppm in an embodiment, from about 10 ppm to about 4000 ppm in another embodiment, from about 50 ppm to about 2000 ppm in another embodiment, and from about 50 ppm to about 500 ppm in yet another embodiment, all based on the total weight of the slurry. In an embodiment, the corrosion inhibitor is present a level between 0.0005% by weight (5 ppm) and 0.1% by weight (1000 ppm).

Carboxylic acids, if added, may also impart corrosion inhibition properties to the slurry composition.

If desired, to increase further the selectivity for removal of certain metals relative to dielectric and/or base wafer material during CMP, fluorine-containing compounds may be added to the slurry composition. Suitable fluorine-containing compounds include, for example, hydrogen fluoride, perfluoric acid, alkali metal fluoride salt, alkaline earth metal fluoride salt, ammonium fluoride, tetramethylammonium fluoride, ammonium bifluoride, ethylenediammonium difluoride, diethylenetriammonium trifluoride, and mixtures thereof. The fluorine-containing compounds may be present in the slurry composition in a concentration of about 0 weight % to about 5 weight % in an embodiment, preferably from about 0.65 weight % to about 5 weight % in another embodiment, from about 0.5 weight % to about 2 weight % in yet another embodiment, all based on the total weight of the slurry. A suitable fluorine-containing compound is ammonium fluoride.

Suitable non-polymeric nitrogen-containing compounds (amines, hydroxides, etc.) that may be added to the slurry composition include, for example, ammonium hydroxide, monoethanolamine, diethanolamine, triethanolamine, diethyleneglycolamine, N-hydroxylethylpiperazine, and mixtures thereof. These non-polymeric nitrogen-containing compounds may be present in the slurry composition in a concentration of about 0 weight % to about 1 weight %, and, if present, are normally present at a level of about 0.01 weight % to about 0.2 weight % of the total weight of the slurry. A preferred non-polymeric nitrogen-containing compound is ammonium hydroxide and is most preferably present in a concentration of about 0.01 weight % to about 0.1 weight % of the total weight of the slurry.

Still other chemicals that can be added to the slurry compositions are biological agents such as bactericides, biocides and fungicides especially if the pH is around about 6 to 9. Suitable biocides, include, but are not limited to, 1,2-benzisothiazolin-3-one; 2(hydroxymethyl)amino ethanol; 1,3-dihydroxymethyl-5,5-dimethylhydantoin; 1-hydroxymethyl-5,5-dimethylhydantion; 3-iodo-2-propynyl-butylcarbamate; glutaraldehyde; 1,2-dibromo-2,4-dicyanobutane; 5-chloro-2-methyl-4-isothiazoline-3-one; 2-methyl-4-isothiazolin-3-one; and mixtures thereof. Preferred biocides are isothiazolines and benzisothiazolines. When present, a biocide is usually present in a concentration of about 0.001 weight % to about 0.1 weight % of the total weight of the slurry.

A dilute slurry, having only enough ingredients to complete the polishing satisfactorily, is preferred because of cost and because of costs associated with waste disposal. In an embodiment, the first CMP slurry comprises between 0.01% and 5%. For example 0.75% to 1.5%, by weight of periodic acid, between 0.3% and 1.5% by weight of ammonium hydroxide, between 1% and 6% by weight of silica abrasive, and wherein the pH is between about 8 and about 14. In an embodiment, the pH of the first CMP slurry is basic. Surfactants, particularly selected nonionic and amphoteric surfactants, are most useful in amounts between 10 ppm and 200 ppm. Citric acid salts, ammonium oxalate monohydrate salts, or both are most useful in amounts between 0.01% and 0.1%. Corrosion inhibitors are most useful in amounts between 10 ppm and 200 ppm. Amino acids chelators are most useful in amounts between 0.01% and 0.1%.

### CMP Method

The CMP method utilized in this invention entails use of the aforementioned composition (as disclosed supra) for chemical mechanical planarization of backside of a base wafer (e.g., a silicon wafer) during through-base wafer processing. In an embodiment, the base wafer is a silicon wafer.

A base wafer in this invention has both front and back sides and the front side has integrated circuits disposed thereon. The base wafer comprises at least one conductive via comprising conductive metal and the at least one conductive via extends from the front of the base wafer at least partially through the base wafer. The conductive metal of the at least one conductive via can in general be any conductive metal that is a solid at ambient temperature. Conductive metals such as mercury and various alloys that are not solids (e.g., liquids) under ambient conditions of temperature and pressure are excluded as possible materials for conductive vias in this invention. Examples of conductive metals are copper, tungsten, and aluminum. In an embodiment, the conductive metal is copper. In another embodiment, the conductive metal is selected from the group consisting of copper and tungsten.

In the method of this invention, the front side of the (first) base wafer is affixed to a carrier. The carrier can be any material that is capable of acting as a suitable support for the base wafer during subsequent CMP processing (as described below). Suitable carrier materials include, but are not limited to, steel, glass, and various polymers, such as polyethylene, polypropylene, and poly (vinyl chloride).

In the method of this invention, affixing the front side of the base wafer having integrated circuits thereon to the carrier can be done in any manner known in the art. An example is use of a suitable adhesive to temporarily bond the front side of a base wafer to the carrier while CMP processing and/or grinding is being performed on the back side of the base wafer. Affixing the base wafer to the carrier affords a base wafer/carrier as a sandwich structure with the back side of the base wafer being an outer surface.

A grinding step to remove a significant amount of material from the back side of the first base wafer may or may not be performed on the base wafer/carrier prior to CMP processing to planarize the back side of the base wafer. Any grinding process known in the art can be utilized. In an embodiment, the back side of the base wafer is not subjected to a grinding step before chemically mechanically polishing the back side of the base wafer. In another embodiment, the back side of the base wafer is subjected to a grinding step before chemically mechanically polishing the back side of the base wafer

Next, following the grinding step if it is done, according to the method of this invention, the backside of the base wafer/carrier is placed such that the back side of the base wafer is face-down on a polishing pad which is fixedly attached to a rotatable platen of a CMP polisher. In this manner, the back side of the base wafer to be polished and planarized is placed in direct contact with the polishing pad. A wafer carrier system or polishing head is used to hold the base wafer/carrier in place and to apply a downward pressure against the back side of the base wafer/carrier during CMP processing while the platen and the substrate are rotated. The polishing composition (first CMP slurry) is applied (usually continuously) on the pad during CMP processing to effect the removal of material from the back side of the base wafer (e.g., silicon wafer). According to this invention, the method utilizing the first CMP slurry will polish the first base wafer at a rate of at least 5,000 angstroms per minute at 7 psi or less of down-force.

In an embodiment, the method utilizing the first CMP slurry will polish the first base wafer at a rate of at least 7,500 angstroms per minute at 7 psi or less of down-force. In an embodiment, the method utilizing the first CMP slurry will polish the first base wafer at a rate of at least 10,000 angstroms per minute at 7 psi or less of down-force. In an embodiment, the method utilizing the first CMP slurry will polish the first base wafer at a rate of at least 12,000 angstroms per minute at 7 psi or less of down-force. In an embodiment, the method utilizing the first CMP slurry will polish the first base wafer at a rate of at least 15,000 angstroms per minute at 7 psi or less of down-force. High base wafer removal rates are essential to the utility of the invention, as a large amount of base layer material is typically removed.

Following CMP processing as described above to thin and planarize the back side of the first base wafer, the carrier will then usually be removed and the resulting thinner base wafer will be used in fabricating a through-base wafer device.

In an embodiment, a method using a pre-treatment slurry may be utilized in chemically mechanically polishing the back side of the base wafer prior to polishing the back side of the base wafer with the first CMP slurry, wherein the method using said pre-treatment slurry polishes the base wafer at a rate of at least 5000 angstroms per minute at a down force of 7 psi. The composition of the pre-treatment slurry can be the same as described for the first CMP slurry.

The present invention is further demonstrated by the examples below.

### EXAMPLES

The sources of materials used in the examples are provided below:

Chemical Components:
1. Syton SR330® obtained from DuPont Air Products NanoMaterials, L.L.C., Tempe Ariz. which contains abrasive and Cu chelators.
2. Syton HT-50 obtained from DuPont Air Products NanoMaterials, L.L.C., Tempe Ariz., (34-52 nm size, Na stabilized)
3. Citric Acid, 29% KMG Electronic Chemicals, Inc, Orange, Calif.
4. Glycine, Chattem Chemicals,
5. Ammonium Hydroxide, 29% KMG Electronic Chemicals, Inc, Orange, Calif.
6. Periodic Acid, DuPont Air Products NanoMaterials, L.L.C., Tempe, Ariz.
7. Mafo13MOD1, BASF Corporation, Florham Park, N.J., ethoxylated amine
8. Daetec MI-110, Daetec L.L.C., Camarmillo, Calif.
9. Iconol TDA-9, BASF Corporation, Florham Park, N.J., ethoxylated alcohol
10. Iconol TDA-6, BASF Corporation, Florham Park, N.J., ethoxylated alcohol
11. Tetra methyl ammonium hydroxide 25% (TMAH), Air Products Chemicals, Inc. Allentown, Pa.
12. Catechol 99%, Acros Organics
13. Guanidine carbonate 99%, Sigma Alcrich
14. Kathon, Air Products Chemicals, Inc. Allentown, Pa.
15. Diethylenetriamine 99%, Sigma Alrich
16. Nitric acid, metal grade, Fisher
17. Acetic acid, glacial, Acros Organics
18. CDI4302D, King Industries, modified triazole compound (diluted with Di H₂O)
19. Ammonium oxalate monohydrate, Acros Organics

Polishing Pads:
1. IC1000 from Rodel, Inc, Phoenix, Ariz.
2. IC1010 from Rodel, Inc, Phoenix, Ariz.
3. 711 from Thomas West Inc, Tex.

Symbols and Definitions:
1. CMP is chemical mechanical planarization =chemical mechanical polishing
2. Å is angstrom(s), a unit of length
3. Å/min is a polishing rate in angstroms per minute
4. psi is pounds per square inch
5. BP is back pressure in psi
6. PS is the platen rotation speed of the polishing tool in, rpm (revolution(s) per minute)
7. SF is the slurry flow in ml/min
8. CS is carrier speed
9. DF is down force in psi
10. min is minute(s)
11. ml is milliliter(s)
12. mV is millivolt(s)
13. NA means data not available

All concentrations of components are wt. % unless otherwise indicated.

Wafers:
1. Silicon blanket wafers, Silicon Valley Microelectronics, Inc., Santa Clara, Calif. 725 μm thickness
2. Copper blanket wafers, Silicon Valley Microelectronics, Inc., Santa Clara, Calif. 15-20 k thickness
3. TiN blanket wafers, Silicon Valley Microelectronics, Inc., Santa Clara, Calif. 3K thickness
4. TEOS blanket wafers, ATDF, Austin, Tex. 15K thickness

Metrology:
1. Mettler AE 160 Analytical Balance
2. Nikon BF DF DIC L200 Microscope
3. Veeco VX300 AFP

Polishing Tools and Processes:
1. IPEC Planar 472 (IPEC), Examples 1-19
   a. Pads were broken in by: 1^{st} with 7 lbs. down force 100 sweep condition process and 2^{nd}, 12 filler wafers are run with control slurry prior to test wafers.
   b. Polishing recipe:
      DF: 7 psi
      Table Speed: 110 rpm
      Head speed: 112 rpm
      Slurry Flow Rate: 200 ml/min
      Conditioner Force: 5 lb.
2. Mirra®, Examples 20-44
   a. The CMP Mirra® tool was manufactured by Applied Materials, 3050 Boweres Avenue, Santa Clara, Calif., 95054. An IC1010, manufactured by Rodel, Inc, 3804 East Watkins Street, Phoenix, Ariz. 85034 was used on platen 1 for polishing the blanket Silicon and copper wafers to obtain removal rates and selectivity.
   b. Pads were broken in by: 1^{st} with a 7 lbs. down force 18 minute condition process and 2^{nd}, 12 filler wafers are run with control slurry prior to test wafers.
   c. Polishing recipe:
      DF: 6 psi
      Table Speed: 120 rpm
      Head speed: 112 rpm
      Slurry Flow Rate: 200 ml/min
      Conditioner Force: 7 lb.

In all examples water formed the balance of the slurry composition. In examples 1 and 2 the effect of H₂O₂ can be seen on Syton® SR330. Hydrogen peroxide was found to be unsuitable for the compositions useful for this invention. See table 1.

TABLE 1
Examples of TSV Formulations: Effect of H2O2 on Control

| | | Example 2: |
|---|---|---|
| | Example 1: | Control |
| | Control | SR330 |
| | SR330 | w/H₂O₂ |
| Component | As-is | pH 11 |
| Syton ® SR330 (wt %, commercial product | 2.4 | 2.38 |
| diluted before H₂O₂ addition) | | |
| H₂O (wt %) | 97.6 | 96.62 |
| Citric acid (wt %) | 0 | 0 |
| Catechol (wt %) | 0 | 0 |
| Ammonium hydroxide (wt %) | 0 | 0 |
| TMAH (wt %) | 0 | 0 |
| Colloidal Silica (wt %) | 0 | 0 |
| H₂O₂ (wt %) | 0 | 1 |
| PIA (wt %) | 0 | 0 |
| pH before H₂O₂ | ~11 | ~11 |
| pH after H₂O₂ | — | ~10.8 |
| Removal rates of Cu (Å/min) at 7 psi | 60 | 32 |
| Removal rates of Silicon (Å/min) at 7 psi | 12000 | 0 |
| Si:Cu Selectivity | 255 | 0 |

— = not applicable

Examples 3-5 show the comparison of different types of oxidizers: using H₂O₂ results in little to no copper removal and no silicon removal, while periodic acid (PIA) has both significant copper removal and silicon removal as shown by the data in Table 2. To get a Si:Cu Selectivity near 1, however, the copper removal rate needs to be greatly increased.

TABLE 2
Additional Examples of TSV Formulations:
Effects of Type of Oxidizer and Concentration

| | Example 3: | Example 4: | Example 5: |
|---|---|---|---|
| | 20675-38-2 | 20675-58-2 | 20675-58-3 |
| Component | w/1% H₂O₂ | w/1% PIA | w/3% PIA |
| Syton ® SR330 | 2.38 | 0 | 0 |
| (commercial product diluted | | | |
| before H₂O₂) | | | |
| H₂O | 96.62 | Balance | Balance |
| HT 50 | 0 | 5 | 5 |
| TMAH | 0 | 3 | 3 |
| NH4OH | 0 | 0 | 0 |
| Guanidine Carbonate | 0 | 5 | 5 |
| Kathon | 0 | 0.0001 | 0.0001 |
| H₂O₂ | 1 | 0 | 0 |
| PIA | 0 | 1 | 3 |
| pH before PIA | 10.31 | 13.34 | 13.16 |
| pH after PIA or H₂O₂ | 10.2 | 13.16 | 11.45 |
| Removal rates of Cu (Å/min) | 32 | 2476 | 4368 |
| at 7 psi | | | |
| Removal rates of Silicon | 0 | 15502 | 12466 |
| (Å/min) at 7 psi | | | |
| Si:Cu Selectivity | 0 | 6.3 | 2.9 |

Examples 6 and 7 show the difference in pH on Si:Cu selectivity and removal rates. At the pH of 11 the copper and silicon blanket removal rates are higher. See Table 3.

TABLE 3
Additional Examples of TSV Formulations: Effects of pH

| | Example 6: | Example 7: |
|---|---|---|
| Component* | pH 11 | pH 7 |
| Colloidal Silica (wt %) | 5 | 5 |
| PIA (wt %) | 1 | 1 |
| pH before PIA | 11.94 | 6.88 |
| pH after PIA | 10.92 | 1.77 |
| Removal rates of Cu (Å/min) at 7 psi, | 5904 | 208 |
| 30 sec | | |
| Removal rates of Silicon (Å/min) at 7 psi, | 6317 | 4253 |
| 600 sec | | |
| Si:Cu Selectivity | 1 | 20 |

*Water is the balance of the composition for each example.

Examples 8-12 show the effect of different chelators using 1% PIA and 5% silica abrasive. These chelators boost the silicon and copper blanket removal rates compared to the control. However, silicon removal rates remain very much above the copper removal rates. See Table 4.

TABLE 4
Additional Examples of TSV Formulations: Effects of Chelators

| | Example | Example | | | |
|---|---|---|---|---|---|
| | 8: | 9: | Example | Example | Example |
| | 2 wt. % | 5 wt. % | 10 | 11: | 12: |
| Component* | DETA | DETA | G.C. | DETA | TMAH |
| diethylenetriamine | 2 | 5 | 0 | 5 | 0 |
| Guanidine Carbonate (wt | 0 | 0 | 5 | 0 | 0 |
| %) | | | | | |
| TMAH (wt %) | 0 | 0 | 3 | 3 | 3 |
| EDTA salt | 0 | 0 | 0 | 0 | 5 |
| Kathon (wt %) | 0 | 0 | 0.0001 | 0.0001 | 0.0001 |
| Colloidal Silica (wt %) | 5 | 5 | 0 | 5 | 5 |
| HNO3 | 0 | 0 | 0 | 0 | 0 |
| PIA (wt %) | 1 | 1 | 1 | 1 | 1 |
| pH before PIA | 11.57 | 11.74 | 13.34 | 10.98 | 13.65 |
| pH after PIA | 10.28 | 10.8 | 13.16 | 10.58 | 13.23 |
| Removal rates of Cu | 815 | 1092 | 2476 | 1394 | 1736 |
| (Å/min) at 7 psi, 30 sec | | | | | |
| Removal rates of Silicon | 14138 | 13790 | 15502 | 13901 | 11820 |
| (Å/min) at 7 psi, 600 sec | | | | | |
| Si:Cu Selectivity | 17 | 12.6 | 6 | 10 | 7 |

*Water is the balance of the composition for each example.

In examples 13-16, other selected copper chelators were evaluated with 1% PIA and 5% silica abrasive. Although the copper removal rate is high, it is possible that the acids are etching the copper, and if so the resulting topography would be less than ideal.

TABLE 5
Examples of TSV Formulations: Effect of chelators

| | Example | Example | Example | Example |
|---|---|---|---|---|
| Component* | 13: | 14: | 15: | 16: |
| Citric acid (wt %) | 0.05 | 0 | 0 | 0.05 |
| Glycine (wt %) | 1 | 0 | 0 | 0 |
| Ammonium hydroxide (wt %) pH | To adjust | To adjust | To adjust | To adjust |
| adjuster before PIA | pH (<1.5 wt | pH (<1.5 wt | pH (<1.5 wt | pH (<1.5 wt |
| | %) | %) | %) | %) |
| Nitric Acid | 0 | 0.05 | 0 | 0 |
| Acetic Acid | 0 | 0 | 0.05 | 0 |
| Colloidal Silica (wt %) | 5 | 5 | 5 | 5 |
| PIA (wt %) | 1 | 1 | 1 | 1 |
| pH before PIA | 10.91 | 10.99 | 10.99 | 11 |
| pH after PIA | 10.76 | 9.83 | 9.98 | 9.95 |
| Removal rates of Cu (Å/min) at | (>24000)^{#} | 15656 | (>28000)^{#} | 14026 |
| 7 psi, 30 sec | | | | |
| Removal rates of Silicon (Å/min) at | 16424 | 9630 | 16701 | 9781 |
| 7 psi, 600 sec | | | | |
| Si:Cu Selectivity | 0.69 | 0.62 | 0.59 | 0.70 |

^{#}All copper on these wafers were removed so a lower limit for the Cu removal rate is reported.
*Water is the balance of the composition for each example.

Examples 17-19 show the effect of pad type using a preferred formulation having 0.05% citric acid salts, 0.01% glycine, 1% PIA, 5% silica abrasive, and ammonium hydroxide to get the pH to 10.2. The same sample was run on 3 different types of pads to determine their effect on selectivity and removal rates. See Table 6.

TABLE 6
Examples of TSV Formulations: Effect of pad type

| | Example | Example | Example |
|---|---|---|---|
| Component | 17 | 18 | 19 |
| Pad | Thomas | IC1000 | IC1010 |
| | West 711 | | |
| Citric acid (wt %) | 0.05 | 0.05 | 0.05 |
| Glycine (wt %) | 0.01 | 0.01 | 0.01 |
| Ammonium hydroxide (wt %) | Enough to | Enough to | Enough to |
| pH | | | |
| adjuster before PIA | adjust pH | adjust pH | adjust pH |
| | (<1.5 wt %) | (<1.5 wt %) | (<1.5 wt %) |
| Colloidal Silica (wt %) | 5 | 5 | 5 |
| PIA (wt %) | 1 | 1 | 1 |
| pH before PIA | 10.91 | 10.91 | 10.91 |
| pH after PIA | 10.2 | 10.2 | 10.2 |
| Removal rates of Cu (Å/min) | 15260 | 14064 | 14678 |
| at 7 psi, 60 sec | | | |
| Removal rates of Silicon | 11590 | 12816 | 15921 |
| (Å/min) at 7 psi, 10 min. | | | |
| Si:Cu Selectivity | 0.76 | 0.91 | 1.08 |

*Water is the balance of the composition for each example.

It can be seen that the composition must be tunable to account for variety in polishing conditions, that is, even to account for using different pads. Examples 20-24 show the effect of different corrosion inhibitors at 100 ppm. The static etch rate (SER) at room temperature and at 40 C of copper for some of these components can be seen in Tables 15 (without PIA) and 16 (with varying amounts of PIA). Low static etch rate, that is, below 300 angstroms per minute at 16 C and at 40 C, is desirable. Surprisingly, addition of some known copper corrosion inhibitors, e.g., benzotriazole (BTA) and DP512, resulted in static etch rates greater than that exhibited by compositions having no corrosion inhibitor. Certain inhibitors, MAFO and Daetec, provided superior static etch rates protection. Each corrosion inhibitor listed afforded a different SER; however, as seen in Table 7 the copper removal rates are similar on blanket wafers. The Cu removal rates are so high during polishing that most corrosion inhibitors have only minor effect during polishing. Note barrier layer removal rates remain low, and TiN can be incorporated as a stopping layer.

TABLE 7
Examples of TSV Formulations: Effect of Corrosion Inhibitors

| | | | | Example | |
|---|---|---|---|---|---|
| | Example | Example | Example | 23: | Example |
| | 20: | 21: | 22: | 100 ppm | 24: |
| | 100 ppm | 100 ppm | 100 ppm | MAFO13 | 100 ppm |
| Component | Daetec | DP512 | BTA | MOD1 | CDI4302D |
| Citric acid (wt %) | 0.05 | 0.05 | 0.05 | 0.05 | 0.05 |
| Glycine (wt %) | 0.01 | 0.01 | 0.01 | 0.01 | 0.01 |
| Ammonium hydroxide (wt %) pH | Enough to | Enough to | Enough to | Enough to | Enough to |
| adjuster before PIA | adjust pH | adjust pH | adjust pH | adjust pH | adjust pH |
| | (<1.5 wt %) | (<1.5 wt %) | (<1.5 wt %) | (<1.5 wt %) | (<1.5 wt %) |
| BTA (wt %) | 0 | 0 | 0.01 | 0.002 | 0.002 |
| DP512 | 0 | 0.01 | 0 | 0 | 0 |
| Daetec | 0.01 | 0 | 0 | 0 | 0 |
| Mafo13MOD1 | 0 | 0 | 0 | 0.01 | 0 |
| CDI4302D | 0 | 0 | 0 | 0 | 0.01 |
| Colloidal Silica (wt %) | 5 | 5 | 5 | 5 | 5 |
| PIA (wt %) | 1 | 1 | 1 | 1 | 1 |
| pH before PIA | 10.99 | 10.98 | 10.98 | 10.9 | 10.9 |
| pH after PIA | 10.5 | 10.4 | 10.3 | 10.7 | 10.2 |
| Removal rates of Cu (Å/min) at 7 psi, | 7298 | 8638 | 6874 | 9280 | 8778 |
| 30 sec | | | | | |
| Removal rates of Silicon (Å/min) at | 13807 | 13797 | 14584 | 12484 | 15631 |
| 7 psi, 30 sec | | | | | |
| Removal rates of TiN at 7 psi, 30 sec | NA | NA | NA | 1768 | 1560 |
| Si:Cu Selectivity | 0.53 | 0.63 | 0.47 | 0.74 | 0.56 |

* Water is the balance of the composition for each example.

MAFO13MOD1, which comprises a blend of one or more polyethoxylated fatty amino carboxylates and one or more polyethoxylated fatty amines, e.g. a tertiary polyethoxylated fatty amine having two polyethylene oxide groups attached to the amine nitrogen. MAFO13MOD1 produced the best SER results. As the concentration of this component increases, the copper and TEOS removal rates decrease.

TABLE 8
Examples of TSV Formulations: Effect of concentration of Corrosion Inhibitors

| | Example | Example | Example | Example |
|---|---|---|---|---|
| | 25: | 26: | 27: | 28: |
| | 10 ppm | 25 ppm | 50 ppm | 100 ppm |
| Component* | MAFO | MAFO | MAFO | MAFO |
| Citric acid (wt %) | 0.05 | 0.05 | 0.05 | 0.05 |
| Glycine(wt %) | 0.01 | 0.01 | 0.01 | 0.01 |
| Ammonium hydroxide (wt %) | To adjust | To adjust | To adjust | To adjust |
| pH adjuster before PIA | pH (<1.5 wt | pH (<1.5 wt | pH (<1.5 wt | pH (<1.5 wt |
| | %) | %) | %) | %) |
| MAFO13MOD1(wt %) | 0.001 | 0.0025 | 0.005 | 0.01 |
| Colloidal Silica (wt %) | 5 | 5 | 5 | 5 |
| PIA (wt %) | 1 | 1 | 1 | 1 |
| pH after PIA | 10.97 | 10.96 | 10.85 | 10.9 |
| pH after PIA | 10.4 | 10.5 | 10.6 | 10.7 |
| Removal rates of Cu (Å/min) at | 10884 | 10598 | 9384 | 9280 |
| 7 psi, 30 sec | | | | |
| Removal rates of Silicon | 13085 | 12847 | 11856 | 12484 |
| (Å/min) at 7 psi, 300 sec | | | | |
| Removal rates of TiN (Å/min) | 1042 | 1016 | 898 | 1768 |
| at 7 psi, 30 sec | | | | |
| Removal rates of TEOS | 1134 | 1088 | 1015 | NA |
| (Å/min) at 7 psi, 30 sec | | | | |
| Si:Cu Selectivity | 0.83 | 0.82 | 0.79 | 0.74 |

TEOS = Tetraethylorthosilicate
*Water is the balance of the composition for each example.

Examples 29-30 show the effect of the concentration of BTA in the slurry. As the BTA concentration increases, the Cu removal rate is suppressed, though a portion of the Cu removal rate difference might be due to the higher pH in Example 29. BTA is a known copper corrosion inhibitor, however the SER data collected shows that other corrosion inhibitors are more effective at protecting copper in a PIA (periodic acid) environment. BTA might be useful if used at very low rates of 0.0005% to 0.005% by weight and with other more effective corrosion inhibitors (e.g., amphoteric inhibitors).

TABLE 9
Examples of TSV Formulations: Effect of concentration
of BTA corrosion Inhibitor

| | Example 29: | Example 30: |
|---|---|---|
| Component | 20 ppm BTA | 100 ppm BTA |
| Citric acid (wt %) | 0.05 | 0.05 |
| Glycine (wt %) | 0.01 | 0.01 |
| Ammonium hydroxide (wt %) pH | Enough to | Enough to |
| adjuster before PIA | adjust pH | adjust pH |
| | (<1.5 wt %) | (<1.5 wt %) |
| BTA (wt %) | 0.002 | 0.01 |
| Colloidal Silica (wt %) | 5 | 5 |
| PIA (wt %) | 1 | 1 |
| pH before PIA | 10.97 | 10.98 |
| pH after PIA | 10.5 | 10.3 |
| Removal rates of Cu (Å/min) at | 10980 | 6874 |
| 7 psi, 30 sec | | |
| Removal rates of Silicon (Å/min) | 14081 | 14584 |
| at 7 psi, 300 sec | | |
| Si:Cu Selectivity | 0.78 | 0.47 |

*Water is the balance of the composition for each example.

Examples 31-34 show the effect of PIA concentration with 50 ppm MAFO13 MOD1 (a amphoteric surface-active agent). Surfactant concentrations of 10 to 200 ppm, for example from 50 to 100 ppm, are useful. At 1.25% PIA the Si:Cu selective is at 0.97. This component, MAFO13 MOD1 afforded the best SER result, which is shown in Table 15 and Table 16.

TABLE 10
Examples of TSV Formulations: Effect of Oxidizer concentration

| | Example | Example | Example | Example |
|---|---|---|---|---|
| Component | 31: | 32: | 33: | 34: |
| Citric acid (wt %) | 0.05 | 0.05 | 0.05 | 0.05 |
| Glycine(wt %) | 0.01 | 0.01 | 0.01 | 0.01 |
| Ammonium hydroxide (wt %) pH | To adjust | To | To | To adjust |
| adjuster before PIA | pH (<1.5 wt | adjust | adjust | pH (<1.5 wt |
| | %) | pH (<1.5 wt | pH (<1.5 wt | %) |
| | | %) | %) | |
| MAFO13MOD1(wt %) | 0.005 | 0.005 | 0.005 | 0.005 |
| Colloidal Silica (wt %) | 5 | 5 | 5 | 5 |
| PIA (wt %) | 0.1 | 0.5 | 1 | 1.25 |
| pH before PIA | 10.98 | 10.96 | 10.85 | 10.93 |
| pH after PIA | 10.92 | 10.8 | 10.3 | 10.5 |
| Removal rate, Cu (Å/min) at 7 psi, | 2610 | 6322 | 9384 | 12082 |
| 30 sec | | | | |
| Removal rate, Silicon (Å/min) at | 9924 | 12078 | 11856 | 12482 |
| 7 psi, 300 sec | | | | |
| Removal rate, TiN (Å/min) at 7 psi, | 882 | 642 | 898 | 770 |
| 30 sec | | | | |
| Removal rate, TEOS (Å/min) at | 778 | 1025 | 1015 | 1245 |
| 7 psi, 30 sec | | | | |
| Si:Cu Selectivity | 0.26 | 0.52 | 0.79 | 0.97 |

TEOS = Tetraethylorthosilicate
*Water is the balance of the composition for each example.

In examples 35-37, the effect of PIA concentration varies from 0.25% to 2%. As seen also in the previous table, the copper removal rate can be tuned with the amount of oxidizer. At 1% PIA, when used in conjugation with 50 ppm Daetec (proprietary corrosion inhibitor), there was found an approximate 1:1 selectivity of Si:Cu.

TABLE 11
Examples of TSV Formulations: Effect of Oxidizer concentration

| | Example | Example | Example |
|---|---|---|---|
| Component | 35: | 36: | 37: |
| Citric acid (wt %) | 0.05 | 0.05 | 0.05 |
| Glycine(wt %) | 0.01 | 0.01 | 0.01 |
| Ammonium hydroxide | To adjust | To adjust | To adjust |
| (wt %) pH adjuster | pH | pH | pH |
| before PIA | (<1.5 wt %) | (<1.5 wt %) | (<1.5 wt %) |
| Daetec corrosion inhibitor | 0.005 | 0.005 | 0.005 |
| (wt %) | | | |
| Colloidal Silica (wt %) | 5 | 5 | 5 |
| PIA (wt %) | 0.25 | 1 | 2 |
| pH before PIA | 10.97 | 10.98 | 10.98 |
| pH after PIA | 10.9 | 9.8 | 10.8 |
| Removal rate, Cu (Å/min) | 3380 | 15104 | 4790 |
| at 7 psi, 30 sec | | | |
| Removal rate, Silicon | 12714 | 14712 | 11281 |
| (Å/min) at 7 psi, 300 sec | | | |
| Removal rate, TiN | 1270 | 1126 | 856 |
| (Å/min) at 7 psi, 30 sec | | | |
| Removal rate, TEOS | 717 | 1145 | 596 |
| (Å/min) at 7 psi, 30 sec | | | |
| Si:Cu Selectivity | 0.27 | 1.02 | 0.42 |

TEOS = Tetraethylorthosilicate
*Water is the balance of the composition for each example.

Example 38 resulted in a 0.91 selectivity of Si:Cu. In this example, ammonium oxalate monohydrate was tested to aid in cleaning residue from the pad. The addition of PIA to the slurry will form salts that stain and possibly glaze the pad. The ammonium oxalate monohydrate acts as a chelator to prevent the salt formation. This component also boosted the Cu removal rate.

TABLE 12
Examples of TSV Formulations: Effect of Corrosion Inhibitors

| Component* | Example 38 |
|---|---|
| Citric acid (wt %) | 0.05 |
| Glycine (wt %) | 0.01 |
| Ammonium Oxalate monohydrate | 0.05 |
| Ammonium hydroxide (wt %) pH adjusted | To adjust pH |
| before PIA | (<1.5 wt %) |
| BTA (wt %) | 0.002 |
| Colloidal Silica (wt %) | 5 |
| PIA (wt %) | 1 |
| pH before PIA | 10.93 |
| pH after PIA | 9.88 |
| Removal rate, Cu (Å/min) at 7 psi, 60 sec | 14486 |
| Removal rate, Silicon (Å/min) at 7 psi, 10 min. | 15953 |
| Si:Cu Selectivity | 0.91 |

*Water is the balance of the composition in this example.

Surprisingly, for silicon and copper removal, the amount of abrasive, preferably silica, can range from below 1% to 10% with no real change in Cu and Si polishing rates. In examples 39-42 shown in table 13, the effect of solids concentration on the Si:Cu selectivity was evaluated. The results show that solids at 1 wt. % to 9 wt. % have little to no effect on silicon or copper removal rates. As the solids concentration increased however, the TiN removal rate was found to increase. TiN blanket wafers were tested because TIN can used as the barrier layer in TSV pattern wafers. Low solids slurries, having for example 0.2% to 1% silica abrasive (50 to 100 nanometer in diameter) can be used if the fabricator wants the barrier material to be a stop.

TABLE 13
Examples of TSV Formulations: Effect of Solids

| | Example | Example | Example | Example |
|---|---|---|---|---|
| Component* | 39 | 40: | 41: | 42: |
| Citric acid (wt %) | 0.05 | 0.05 | 0.05 | 0.05 |
| Glycine (wt %) | 0.01 | 0.01 | 0.01 | 0.01 |
| Ammonium hydroxide (wt %) pH | To adjust | To adjust | To adjust | To adjust |
| adjuster before PIA | pH (<1.5 wt | pH (<1.5 wt | pH (<1.5 wt | pH (<1.5 wt |
| | %) | %) | %) | %) |
| BTA (wt %) | 0.002 | 0.002 | 0.002 | 0.002 |
| Colloidal Silica (wt %) | 1 | 3 | 7 | 9 |
| PIA (wt %) | 1 | 1 | 1 | 1 |
| pH before PIA | ~10.9 | ~10.9 | ~10.9 | ~10.9 |
| pH after PIA | 10.5 | 10.4 | 10.5 | 10.6 |
| Removal rate, Cu (Å/min) at 7 psi, | 10716 | 11636 | 11438 | 10006 |
| 30 sec | | | | |
| Removal rate, Silicon (Å/min) at | 15138 | 16350 | 16151 | 15638 |
| 7 psi, 300 sec | | | | |
| Removal rate, TiN (Å/min) at | 708 | 1076 | 1510 | 1788 |
| 7 psi, 30 sec | | | | |
| Si:Cu Selectivity | 0.71 | 0.71 | 0.71 | 0.64 |

*Water is the balance of the composition in this example.

In examples 43 and 44, only abrasive was used to polish silicon and copper blanket wafers. The silicon had a removal rate of approximately 3622 Å/min, while copper was not removed. This type of slurry can be used when trying to achieve large copper protrusions. In comparison, when 1% PIA is added, the selectivity of Si:Cu is 0.75.

TABLE 14
Examples of TSV Formulations: Abrasive with and without oxidizer,

| | Example | Example |
|---|---|---|
| Component* | 43: | 44: |
| Citric acid (wt %) | 0 | 0 |
| Glycine (wt %) | 0 | 0 |
| Ammonium hydroxide (wt %) | 0 | 0 |
| BTA (wt %) | 0 | 0 |
| Colloidal Silica (wt %) | 10 | 10 |
| PIA (wt %) | 0 | 1 |
| pH before PIA | 10.88 | 11.01 |
| pH after PIA | NA | 9.1 |
| Removal rates of Cu (Å/min) at 7 psi, 30 sec | <1 | 9760 |
| Removal rates of Silicon (Å/min) at 7 psi, | 3622 | 13051 |
| 300 sec | | |
| Removal rates of TiN (Å/min) at 7 psi, 30 sec | NA | 884 |
| Removal rates of TEOS (Å/min) at 7 psi, | NA | 2387 |
| 30 sec | | |
| Si:Cu Selectivity | 0.049 | 0.75 |

TEOS = Tetraethylorthosilicate
*Water is the balance of the composition for each example.

Tables 15 and 16 show results of static etch testing on a variety of corrosion inhibitors. MAFO13 MOD1™ provided superior results. The polishing slurry advantageously comprises between 5 ppm and 500 ppm, for example between 25 ppm and 150 ppm, of an amphoteric corrosion inhibitor having the general formula N(R₁, R₂, R₃—X) wherein R₁ can be an alkyl group having between 8 to 30 unbranched carbon atoms; R₂ can be a short alkyl group having from 1 to about 6 unbranched carbon atoms that can have one or more hydroxyl side groups; R₃ can be selected from a polyethylene oxide group having between 3 to 40 ethylene oxide units and a polypropylene oxide group having from 1 to 10 and, more preferably, from 2 to 5 propylene oxide units; and X can be an anionic acid group, an anionic acid ester, or an alkali metal salt of an anionic acid or acid ester, where the acid is preferably sulfonic, carboxylic or phosphoric acid. Another suitable amphoteric surfactant having the general formula N(R₁, R₂, R₃) wherein R1 can be an unbranched alkyl group having from 8 to 30 carbon atoms that forms an aliphatic fatty amine when bound to the nitrogen atom; R2 can be selected from a polyethylene oxide group having between 3 to 40 ethylene oxide units and a polypropylene oxide group having from 1 to 10 and, more preferably, from 2 to 5 propylene oxide units; and R3 can also be a polyethylene oxide group or a polypropylene oxide group, but can also be a hydrogen. A preferred surfactant is a tertiary polyethoxylated fatty amine having two polyethylene oxide groups attached to the amine nitrogen. In a preferred aspect, the amphoteric surfactant in the anode comprises a blend of one or more polyethoxylated fatty amino carboxylates and one or more polyethoxylated fatty amines which we believe forms MAFO13 MOD1™ from BASF Corporation.

TABLE 15
SER Data Comparing Corrosion Inhibitors without PIA

| | Temperature | Static Etch Rate (Å/min), |
|---|---|---|
| Sample | (° C.) | Average of 2 readings |
| control: SR330 | RT | 2.6 |
| no corrosion inhibitor | RT | 102.05 |
| 500 ppm Ammonium Oxalate | RT | 74.7 |
| 100 ppm BTA | RT | Too much corrosion to |
| | | read |
| 100 ppmDP512 | RT | 74.7 |
| 100 ppm Daetec | RT | 67.25 |
| control: SR330 | 40 | 0 |
| no corrosion inhibitor | 40 | 228.2 |
| 500 ppm Ammonium Oxalate | 40 | Too much corrosion to |
| | | read |
| 100 ppm BTA | 40 | Too much corrosion to |
| | | read |
| 100 ppm DP512 | 40 | 286.7 |
| 100 ppm Daetec | 40 | 177.25 |

TABLE 16
SER Data Comparing Corrosion Inhibitors with Concentration of PIA

| | Temperature | |
|---|---|---|
| Sample | (° C.) | Static Etch Rate (Å/min) |
| Control SR330 | RT | 0 |
| 50 ppm MAFO, 0.1% PIA | RT | 50 |
| 50 ppm MAFO, 0.5% PIA | RT | 116 |
| 50 ppm MAFO, 1.25% PIA | RT | 512 |
| Control SR330 | 40 | 0 |
| 50 ppm MAFO, 0.1% PIA | 40 | 262 |
| 50 ppm MAFO, 0.5% PIA | 40 | 277 |
| 50 ppm MAFO, 1.25% PIA | 40 | Too much corrosion, could |
| | | not be read |

In Example 45, removal rates of copper and silicon were determined and selectivity values (Cu/Si) were determined as a function of slurry flow rate. The results obtained are shown below:

| | Slurry Flow Rate | | | |
|---|---|---|---|---|
| | 250 mL/min | 200 mL/min | 150 mL/min | 100 mL/min |
| Si | 13654 | 13656 | 14031 | 14993 |
| Cu | 10144 | 9434 | 8202 | 7096 |
| Selectivity | 0.74 | 0.69 | 0.58 | 0.47 |
| (Cu/Si) | | | | |

ML/min = milliliters per minute

We selected 7 psi downforce for polishing as the back if a wafer can be polished at such a pressure without damage to the wafer. Down pressures from about 3 psi to about 10 psi are preferred. The invention has been illustrated by these selected examples, but should not be construed to be limited to the examples.

1. A method for constructing an assembly comprising at least two base wafers, said method comprising:
a) providing a first base wafer having front and back sides, wherein the front side comprises integrated circuits disposed thereon and wherein the base wafer comprises at least one conductive via comprising conductive metal and extending from the front of the base wafer at least partially through the base wafer;
b) affixing the front side of the base wafer having integrated circuits thereon to a carrier;
c) contacting the back side of the base wafer with a polishing pad and a first CMP slurry, said first CMP slurry comprising:
1) a liquid carrier;
2) between 0.1% and 20% by weight of an oxidizer selected from the group consisting of periodic acid or salt thereof, perchloric acid or salt thereof, a persulfate salt or acid thereof, a permanganate salt or acid thereof, ozone, silver oxide, and elemental fluorine;
3) an abrasive; and
4) at least one metal chelating agent, and
d) polishing the backside of the base wafer until at least one conductive via is exposed, wherein the first base wafer is polished using the first CMP slurry at a rate of at least 5,000 angstroms per minute at 7 psi or less of down-force.

2. The method of claim 1 wherein the first base wafer is a silicon wafer.

3. The method of claim 1 wherein the conductive metal is selected from the group consisting of copper and tungsten.

4. The method of claim 1 wherein the oxidizer is selected from the group consisting of periodic acid or salt thereof, perchloric acid or salt thereof, and a persulfate salt or acid thereof.

5. The method of claim 1 wherein the oxidizer is periodic acid.

6. The method of claim 1 wherein the metal chelating agent comprises an aminocarboxylic acid having the structure H₂N—R—COOH, where R is a straight or branched alkyl group having between 1 and 6 carbon atoms.

7. The method of claim 6 wherein the metal chelating agent further comprises a hydroxy-carboxylic acid.

8. The method of claim 6 wherein the metal chelating agent is glycine.

9. The method of claim 8 wherein the metal chelating agent is glycine in combination with citric acid.

10. The method of claim 1 wherein the first base wafer is polished using the slurry at a rate of at least 10,000 angstroms per minute at 7 psi or less of down-force.

11. The method of claim 1 wherein the slurry further comprises between 0.0005% by weight and 0.1% by weight of a corrosion inhibitor.

12. The method of claim 1 wherein the slurry comprises between 0.01% and 5% by weight of a citrate salt.

13. The method of claim 1 wherein the slurry comprises between 0.01% and 5% by weight of periodic acid, between 0.3% and 1.5% by weight of ammonium hydroxide, and wherein the pH is between about 8 and about 14.

14. The method of claim 1 wherein the liquid carrier comprises water.

15. The method of claim 11 wherein the corrosion inhibitor is a phenolic compound.

16. The method of claim 15 wherein the phenolic compound in the first CMP slurry is catechol present at a level between 0.001% and 5% by weight.

17. The method of claim 1 wherein the first base wafer: conductive metal selectivity ranges from about 0.5 to about 2.0.

18. The method of claim 1 wherein the base wafer is polished using the first CMP slurry at a rate of at least 7,500 angstroms per minute at 7 psi or less of down-force.

19. The method of claim 1 wherein the pH of the first CMP slurry is basic.

20. The method of claim 1 wherein the backside of the base wafer is not subjected to a grinding step before chemically mechanically polishing the backside of the base wafer.

21. The method of claim 1 wherein the backside of the base wafer is subjected to a grinding step before chemically mechanically polishing the backside of the base wafer.

22. The method of claim 1, further comprising the step of CMP of the backside of the base wafer with a pre-treatment slurry prior to polishing the backside of the base wafer with the first CMP slurry, wherein said pre-treatment slurry polishes the base wafer at a rate of at least 5000 angstroms per minute at a down force of 7 psi.

23. The method of claim 1, wherein the at least one conductive via comprising conductive metal and extending from the front of the base wafer further comprises a barrier material adapted to prevent conductive metal from migrating through silicon, said method further comprising the step of polishing the backside of the base wafer with a second CMP slurry after polishing the backside of the base wafer with the first CMP slurry, wherein said second CMP slurry has a conductive metal to barrier material selectivity of between 0.6 and 1.5.

24. The method of claim 1, further comprising electrically connecting a second base wafer comprising at least one exposed via to the at least one conductive via on the backside of the first base wafer.

25. The method of claim 1, further comprising forming circuits on the backside of the first base wafer after polishing the first base wafer, at least a portion of said circuits being electrically connected to the at least one exposed conductive via on the backside of the first base wafer.

26. A method for constructing an assembly comprising two wafers, said method comprising:
a) providing a silicon base wafer having front and back sides, wherein the front side comprises integrated circuits disposed thereon and wherein the silicon base wafer comprises at least one conductive via comprising copper and extending from a front side of the silicon base wafer at least partially through the silicon base wafer;
b) affixing the front side of the silicon base wafer to a carrier; and
c) contacting the back side of the silicon base wafer with a polishing pad and a first CMP slurry, said first CMP slurry comprising:
1) water;
2) between 0.05% and 10% by weight of periodic acid;
3) an abrasive; and
4) at least one of an organic acid or an amino-carboxylic acid, and
d) polishing the backside of the wafer until at least one conductive via is exposed, wherein the first CMP slurry polishes silicon at a rate of at least 10,000 angstroms per minute at 7 psi or less of down-force.

27. The method of claim 26 wherein the backside of the silicon base wafer is not subjected to a grinding step before chemically mechanically polishing the backside of the silicon wafer.

28. The method of claim 26 wherein the first CMP slurry comprises citric acid and glycine.

29. The method of claim 26 wherein the Si: Cu selectivity ranges from about 0.5 to about 1.5.

30. The method of claim 26 further comprising electrically connecting a second silicon wafer comprising at least one exposed via to the at least one conductive via on the backside of the first base wafer.

31. The method of claim 26 wherein the first CMP slurry has a pH of about 10.5 to about 11.5.
